(19) United States
(12) Patent Application Publication
(10) Pub. No.: US 2026/0033207 A1
(43) Pub. Date: Jan. 29, 2026

(54) DISPLAY DEVICE

(71) Applicant: LG Display Co., Ltd., Seoul (KR)

(72) Inventors: Jiyoon CHOI, Paju-si (KR); Byunggwan HYUN, Paju-si (KR); Seunggyun KIM, Paju-si (KR)

(73) Assignee: LG Display Co., Ltd., Seoul (KR)

(21) Appl. No.: 19/258,080

(22) Filed: Jul. 2, 2025

(30) Foreign Application Priority Data
Jul. 29, 2024 (KR) 10-2024-0099912

(51) Int. Cl. H10K 59/38; H10K 59/122; H10K 59/123; H10K 59/131; H10K 59/35; H10K 59/40; H10K 59/80

(52) U.S. Cl. CPC H10K 59/38; H10K 59/122; H10K 59/123; H10K 59/131; H10K 59/35; H10K 59/40; H10K 59/80518; H10K 59/80524; H10K 59/873; H10K 59/8792

(57) ABSTRACT

A display device according to an embodiment includes a substrate, a light-emitting element layer on the substrate, a first encapsulation layer on the light-emitting element layer, a color filter on the first encapsulation layer, and a second encapsulation layer on the color filter.

### CROSS REFERENCE TO RELATED APPLICATION

The present application claims priority to Korean Patent Application No. 10-2024-0099912, filed Jul. 29, 2024, the entire contents of which is incorporated herein for all purposes by this reference.

### BACKGROUND OF THE INVENTION

### Field of the Invention

This specification relates to a display device, and more particularly, to a display device capable of having a narrow bezel and preventing crack propagation.

### Description of the Related Art

With the advancement of the information society, there is an increasing demand for display devices that can show images, and various types of display devices such as liquid crystal display (LCD) devices and organic light emitting diode (OLED) displays are being utilized.

The display device includes a plurality of pixels and is equipped with a plurality of switching elements to drive and control the pixels.

### SUMMARY OF THE INVENTION

It is an object of the embodiments of this specification to provide a display device capable of improving the color purity of light generated from a light-emitting element layer of the display device.

It is another object of the embodiments of this specification to provide a display device capable of securing a viewing angle.

It is another object of the embodiments of this specification to provide a display device capable of improving luminance reduction and driving efficiency.

It is still another object of the embodiments of this specification to provide a display device having a reduced thickness.

The objects of this specification are not limited to those mentioned above, and other technical objects may be inferred from the following embodiments.

In order to accomplish the above object, a display device according to an embodiment includes a substrate, a light-emitting element layer on the substrate, a first encapsulation layer on the light-emitting element layer, a color filter on the first encapsulation layer, and a second encapsulation layer on the color filter.

In order to accomplish the above objects, a display device according to another embodiment includes a substrate including a plurality of sub-pixels, a light-emitting element layer on the substrate, an encapsulation layer including a first encapsulation layer on the light-emitting element layer, a second encapsulation layer on the first encapsulation layer, and a third encapsulation layer on the second encapsulation layer, a first black matrix disposed at the boundary between adjacent sub-pixels, between the first and second encapsulation layers, a color filter disposed between the first black matrix and the second encapsulation layer, a touch layer including a first touch conductive layer disposed on the third encapsulation layer and including a bridge electrode, and a second touch conductive layer disposed on the first touch conductive layer and including a sensor electrode, a second black matrix disposed at the boundary between adjacent sub-pixels on the touch layer, covering the bridge electrode and the sensor electrode, wherein the second black matrix has a width smaller than the width of the first black matrix.

The specific details of other embodiments are included in the detailed description and drawings.

### BRIEF DESCRIPTION OF THE DRAWINGS

FIG. 1 is a plan view of a display device according to an embodiment;

FIG. 2 is a cross-sectional view of a display panel of the display device of FIG. 1 in a bent state;

FIG. 3 is a cross-sectional view taken along line A-A′ of FIG. 1;

FIG. 4 is a detailed cross-sectional view of a lighting-emitting element layer of FIG. 3.

FIG. 5 is a detailed cross-sectional view of a light-emitting element layer of FIG. 3 according to an alternative embodiment;

FIG. 6 is a cross-sectional view of a touch layer of FIG. 3;

FIG. 7 is a cross-sectional view taken along line B-B′ of FIG. 1.

FIG. 8 is a cross-sectional view taken along line C-C′ of FIG. 1.

FIG. 9 is an enlarged cross-sectional view of Q1 area of FIG. 3.

FIG. 10 is an enlarged cross-sectional view of Q2 area of FIG. 9;

FIG. 11 is a cross-sectional view taken along line A-A′ of FIG. 1 of a display device according to another embodiment;

FIG. 12 is a cross-sectional view taken along line B-B′ of FIG. 1 of a display device according to another embodiment; and

FIG. 13 is a cross-sectional view taken along line C-C′ of FIG. 1 of a display device according to another embodiment.

### DETAILED DESCRIPTION OF THE INVENTION

Hereinafter, embodiments will be described with reference to accompanying drawings.

The same reference numerals refer to the same components. Additionally, in the drawings, the thickness, proportions, and dimensions of components may be exaggerated for effective explanation of the technical content. Although depicted in a scale different from their actual scale for the convenience of explanation, the components are not limited to the scale shown in the drawing.

In the specification, when a component (or area, layer, part, etc.) is mentioned as being “on top of,” “connected to,” or “coupled to” another component, it means that it may be directly connected/coupled to the other component, or a third component may be placed between them.

The expression “and/or” is taken to include one or more combinations that can be defined by associated components.

The terms “first,” “second,” etc. are used to describe various components, but the components should not be limited by these terms. The terms are used only for distinguishing one component from another component. For example, a first component may be referred to as a second component and, similarly, the second component may be referred to as the first component, without departing from the scope of the present invention. The singular forms are intended to include the plural forms as well unless the context clearly indicates otherwise.

The terms such as “below,” “lower,” “above,” “upper,” etc. are used to describe the relationship of components depicted in the drawings. The terms are relative concepts and are described based on the direction indicated on the drawing. For example, unless explicitly stated with terms such as “directly” or “immediately,” one or more other components may be positioned between two described components. Spatially relative terms such as “below,” “beneath,” “lower,” “above,” and “upper” may be used to facilitate the description of the relationship between one component or element and another, as illustrated in the drawings. These spatially relative terms should be understood to include different orientations of a component during use or operation, in addition to the orientation shown in the drawings. For instance, if a component shown in the drawings is flipped, a component described as being “below” or “beneath” another component may then be positioned “above” that component. Accordingly, the term “below,” for example, may encompass both upward and downward directions.

It will be further understood that the terms “comprises,” “has,” and the like are intended to specify the presence of stated features, numbers, steps, operations, components, parts, or a combination thereof but are not intended to preclude the presence or possibility of one or more other features, numbers, steps, operations, components, parts, or combinations thereof.

The various features of the embodiments of the disclosure can combined or assembled together, either partially or entirely, in a technically diverse manner, and each embodiment can be independently implemented or in conjunction with related embodiments.

Hereinafter, the display devices according to the embodiments of this specification will be described with reference to the accompanying drawings.

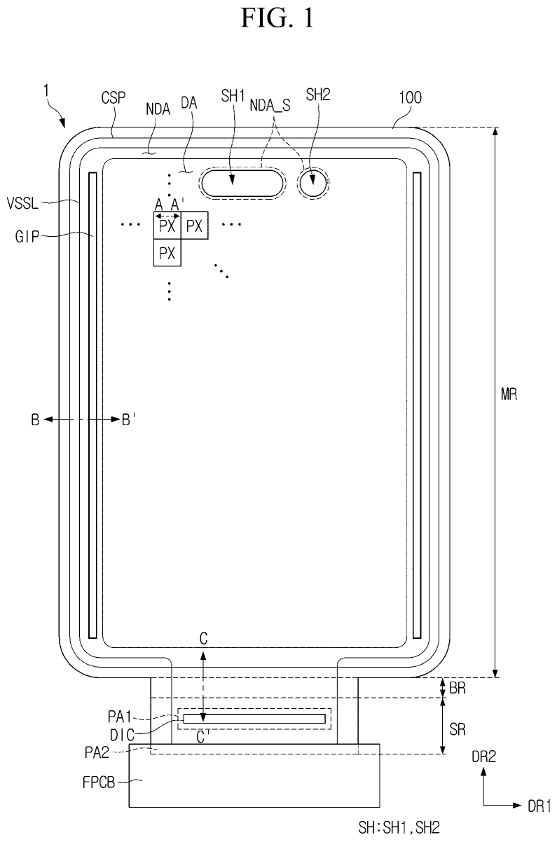

FIG. 1 is a plan view of a display device according to an embodiment.

Referring to FIG. 1, a display device 1 according to an embodiment may include a display panel 100. The display panel 100 may include a display area DA including a plurality of pixels PX and a non-display area NDA surrounding the display area DA. The display area DA may have a rectangular planar shape. However, the display area DA is not limited thereto and may have a square, circular, elliptical, or other polygonal planar shape. For example, the display area DA may have a rounded rectangular shape, but it is not limited thereto and may also be a rectangular shape with sharp corners.

In the embodiments, a first direction DR1 and a second direction DR2 are different directions that intersect each other, such as directions perpendicular to each other in a plan view of the display device 1. In FIG. 1, the first direction DR1 may correspond to the extending direction of the short sides of the display panel 100, while the second direction DR2 may correspond to the extending direction of the long sides of the display panel 100. However, it should be understood that the directions mentioned in the embodiments are relative and are not limited to the specific directions described.

The display area DA may include short sides extending along the first direction DR1 and long sides extending along the second direction DR2. The non-display area NDA may surround the display area DA. The non-display area NDA may be disposed on one side and the other side of the display area DA in the first direction DR1 and on one side and the other side of the display area DA in the second direction DR2.

The display panel 100 may further include sensor non-display areas NDA_S and sensor holes SH surrounded by the sensor non-display areas NDA_S. The sensor holes SH1 and SH2 may be surrounded by the display area DA in a plan view of the display device 1. The sensor holes SH1 and SH2 may, for example, be two in number as shown in FIG. 1, but the embodiments of this specification are not limited thereto. For example, a single sensor hole may be provided. The two sensor holes SH1 and SH2 may be provided for the arrangement of an infrared sensor and a camera sensor, respectively; however, the embodiments of this specification are not limited thereto. The sensor non-display area NDA_S may be disposed between the sensor holes SH1 and SH2 and the display area DA. The sensor non-display area NDA_S may completely surround the sensor holes SH1 and SH2. No pixels PX may be arranged in the sensor non-display area NDA_S.

A gate driving unit GIP may be arranged in the non-display area NDA located on each of one side and the other side of the display area DA in the first direction DR1. A low-potential voltage line VSSL may be disposed outside the gate driving unit GIP in the non-display area NDA. For example, as shown in FIG. 1, the low-potential voltage line VSSL may extend from a flexible printed circuit board FPCB, pass through a sub-region SR and a bending region BR, and be positioned outside the gate driving unit GIP in the non-display area NDA while surrounding the display area DA.

The non-display area NDA located on the other side of the display area DA in the second direction DR2 may extend further in the second direction DR2 from the central portion of the other side of the display area DA. The width in the first direction DR1 of the non-display area NDA, which extends further in the second direction DR2 from the central portion of the other side of the display area DA in the second direction DR2, may be smaller than the width in the first direction DR1 of the non-display area NDA adjacent to the other side of the display area DA in the second direction DR2.

The display panel 100 may include a main region MR, a sub-region SR, and a bending region BR between the main region MR and the sub-region SR. The display area DA and the non-display area NDA surrounding the display area DA on all four sides may form the main region MR, while the portion extending further in the second direction DR2 from the central portion of the other side of the display area DA may constitute the bending region BR and the sub-region SR. The bending region BR may be positioned between the sub-region SR and the main region MR. The sub-region SR may include a first pad area PA1 and a second pad area PA2 located at an end of the sub-region SR away from the bending region BR in the second direction DR2. The display device 1 may further include a data driving unit DIC and a flexible printed circuit board FPCB. The data driving unit DIC may be placed in the first pad area PA1, and the flexible printed circuit board FPCB may be attached to the second pad area PA2. The first pad area PA1 and the second pad area PA2 may each include a number of pads that connect the data driving unit DIC and the flexible printed circuit board FPCB. The data driving unit DIC may, for example, be provided in the form of a driving chip IC, but is not limited thereto. In an embodiment, the data driving unit DIC is arranged in a chip-on-plastic method, directly mounted on the display panel 100, but is not limited thereto, and may also be arranged in a chip-on-glass or chip-on-film method.

The display panel 100 according to an embodiment may further include a crack detection pattern CSP surrounding the low-potential voltage line VSSL. The crack detection pattern CSP may be arranged to completely surround the display area DA, as shown in FIG. 1. For example, the crack detection pattern CSP may be placed on the outer side of the low-potential voltage line VSSL. However, the embodiments of this specification are not limited thereto, and the crack detection pattern CSP may be partially disposed in the non-display area NDA on the other side of the display area DA in the second direction DR2.

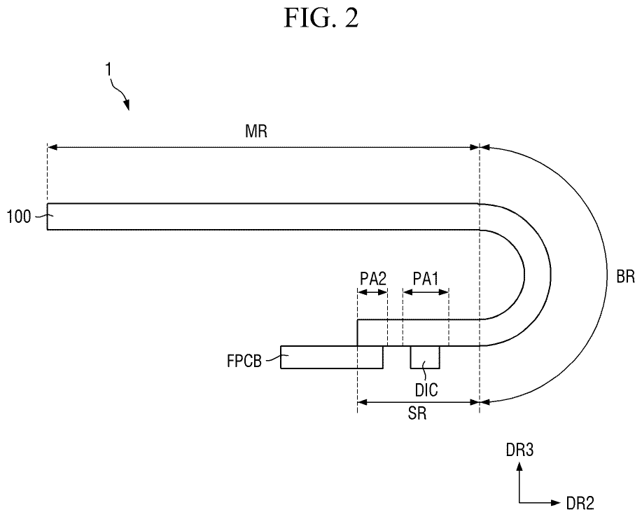

FIG. 2 is a cross-sectional view illustrating a bent state of the display panel in FIG. 1.

Referring to FIG. 2, the bending region BR of the display panel 100 of the display device 1 according to an embodiment may be bent in the thickness direction (or the third direction DR3). Through this, the main region MR and the sub-region SR may overlap in the thickness direction. The display panel 100 may be bent such that the bottom surface of the main region MR and the top surface of the sub-region SR face each other. A flexible printed circuit board FPCB may be attached to the end of the sub-region SR. Thus, the display device 1 may have a narrow bezel.

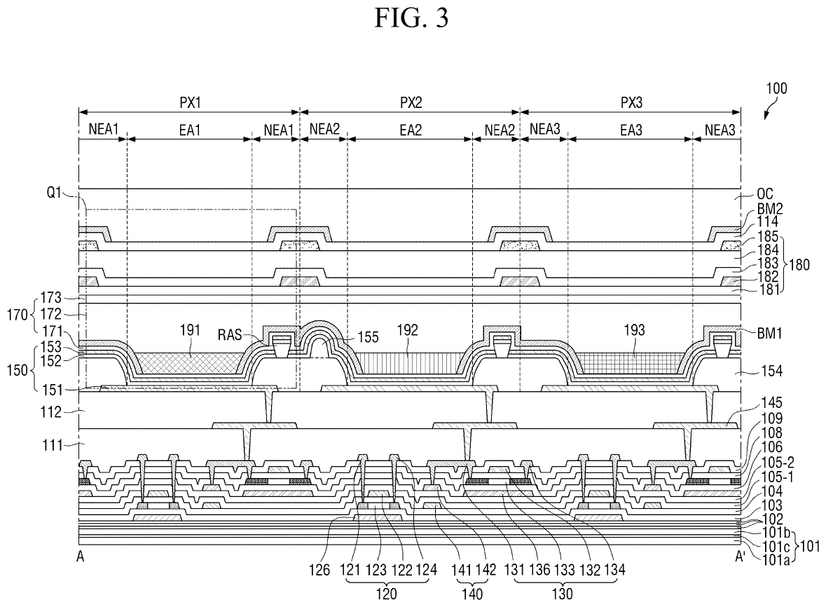

FIG. 3 is a cross-sectional view taken along line A-A′ of FIG. 1;

Referring to FIG. 3, the pixel PX (see FIG. 1) of the display panel 100 may include a plurality of sub-pixels, e.g., a first sub-pixel PX1, a second sub-pixel PX2, and a third sub-pixel PX3. The first sub-pixel PX1 may be a red sub-pixel, the second sub-pixel PX2 may be a green sub-pixel, and the third sub-pixel PX3 may be a blue sub-pixel, but the embodiments of this specification are not limited thereto. In some embodiments, the pixel PX may further include a fourth sub-pixel (not shown), which may be a white sub-pixel, but the embodiments of this specification are not limited thereto.

The display panel 100 may include a substrate 101, a first thin-film transistor 120, a second thin-film transistor 130, a light-emitting element layer 150, an encapsulation layer 170, a first black matrix BM1, first to third color filters 191, 192, and 193, a touch layer 180, an upper insulating layer 114, a second black matrix BM2, and a planarization layer OC. The display panel 100 may include at least one panel insulating layer between the substrate 101 and the light-emitting element layer 150, and at least one touch insulating layer. The at least one panel insulating layer may include at least one of a buffer layer 102, a first insulating layer 103, a second insulating layer 104, a third-1 insulating layer 105-1, a third-2 insulating layer 105-2, a fourth insulating layer 106, a fifth insulating layer 108, a sixth insulating layer 109, a first protective layer 111, and a second protective layer 112, and the at least one touch insulating layer may include at least one of a touch buffer layer 181, a first touch insulating layer 183, and a second touch insulating layer 184.

The substrate 101 may include one or more plastic materials. For example, the substrate 101 may be a multi-layer substrate including a plurality of plastic materials, such as polyimide. For example, the substrate 101 may include a first substrate layer 101a and a second substrate layer 101b, each including a plastic material, and a third substrate layer 101c, which includes an inorganic insulating material between the first and second substrate layers 101a and 101b, but the embodiments of this specification are not limited thereto. Since the substrate 101 has a substantially the same shape as the display panel 100, the substrate 101 may be described to have the display region DA, the non-display region NDA, the bending region BR and the sub-region SR, etc. as discussed with respect to the display panel 100.

The buffer layer 102 may be disposed on the substrate 101. The buffer layer 102 may minimize or delay the diffusion of moisture or oxygen that penetrates into the substrate 101. The buffer layer 102 may be formed by alternately stacking silicon nitride (SiNx) and silicon oxide (Siox) at least once, but the embodiments of this specification are not limited thereto.

A first light-blocking layer 126 may be disposed on the buffer layer 102. The first light-blocking layer 126 may prevent light from passing through a first semiconductor layer 123 of the first thin-film transistor 120. For example, the first semiconductor layer 123 may be disposed to overlap with the first light-blocking layer 126. The first light-blocking layer 126 may be a single layer or multiple layers made of molybdenum (Mo), aluminum (Al), chromium (Cr), nickel (Ni), neodymium (Nd), copper (Cu), or any of their alloys, but the embodiments of this specification are not limited thereto.

The first insulating layer 103 may be disposed on the buffer layer 102 and the first light-blocking layer 126. The first insulating layer 103 may prevent a short circuit between the configuration of the first thin-film transistor 120 and the first light-blocking layer 126. The first insulating layer 103 may be made of the same material as the buffer layer 102, but the embodiments of this specification are not limited thereto. For example, the first insulating layer 103 may be made of an inorganic insulating material, such as silicon nitride (SiNx) or silicon oxide (Siox), but the embodiments of this specification are not limited thereto.

The first thin-film transistor 120 may be disposed on the first insulating layer 103. The first thin-film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor such as Indium-Gallium-Zinc Oxide (IGZO), or a silicon-based semiconductor material such as amorphous silicon or polycrystalline silicon, but the embodiments of this specification are not limited thereto. For example, the first semiconductor layer 123 may be made of a metal oxide semiconductor when the first thin-film transistor 120 is a switching transistor. The first semiconductor layer 123 may include a channel region, a source region, and a drain region.

A polycrystalline semiconductor layer has higher mobility than an amorphous semiconductor layer and an oxide semiconductor layer, so it may have lower power consumption and improved reliability. Therefore, the driving transistor (e.g. the second thin-film transistor 130, which will be described later) may be formed using the polycrystalline semiconductor layer.

The second insulating layer 104 may be disposed on the first semiconductor layer 123. The second insulating layer 104 may be made of the same material as the first insulating layer 103 and may prevent short circuits between the first semiconductor layer 123 and other components of the first thin-film transistor 120.

The first gate electrode 122 may be disposed on the second insulating layer 104. The first gate electrode 122 may be arranged to overlap with the channel region of the first semiconductor layer 123, positioned on the second insulating layer 104. The first gate electrode 122 may be composed of a single layer or multilayer structure that includes materials such as molybdenum (Mo), copper (Cu), titanium (Ti), aluminum (Al), chromium (Cr), gold (Au), nickel (Ni), neodymium (Nd), or their compounds, but the embodiments of this specification are not limited to these materials. The first gate electrode 122 may be arranged along with a gate line for supplying a gate signal to the first thin-film transistor 120. For example, the gate line may be formed in the same layer and made of the same material as the first gate electrode 122, but the embodiments of this specification are not limited thereto.

The third-1 insulating layer 105-1 and the third-2 insulating layer 105-2 may be disposed on the first gate electrode 122. The third-1 insulating layer 105-1 and the third-2 insulating layer 105-2 may be formed by alternating layers of silicon nitride (SiNx) and silicon oxide (Siox) at least once, but the embodiments of this specification are not limited thereto. For example, the third-1 insulating layer 105-1 may include silicon oxide (Siox), and the third-2 insulating layer 105-2 may include silicon nitride (SiNx), but the embodiments of this specification are not limited thereto.

The first source electrode 121 and the first drain electrode 124 may be disposed on the third-1 insulating layer 105-1 and the third-2 insulating layer 105-2.

The first source electrode 121 and the first drain electrode 124 may be electrically connected to the first semiconductor layer 123 through contact holes. The first source electrode 121 and the first drain electrode 124 may be made of a metal material. For example, the first source electrode 121 and the first drain electrode 124 may be composed of a single layer or multiple layers made of any one of molybdenum (Mo), aluminum (Al), chromium (Cr), gold (Au), titanium (Ti), nickel (Ni), neodymium (Nd), copper (Cu), or their alloys, but the embodiments of this specification are not limited thereto.

The first source electrode 121 and the first drain electrode 124 may be arranged along with a data line for supplying a data signal to the first thin-film transistor 120. For example, the data line may be formed in the same layer and made of the same material as the first source electrode 121 and the first drain electrode 124, but the embodiments of this specification are not limited thereto.

A storage electrode 140 may be disposed apart from the first thin-film transistor 120. The storage electrode 140 may include a first storage electrode 141 and a second storage electrode 142.

The first storage electrode 141 may be disposed in the same layer and made of the same material as the first gate electrode 122, but the embodiments of this specification are not limited thereto.

The second storage electrode 142 may be disposed on the first storage electrode 141. The second storage electrode 142 may be disposed on the third-1 insulating layer 105-1 and the third-2 insulating 105-2, and a capacitance may be formed between the first storage electrode 141 and the second storage electrode 142 with the third-1 insulating layer 105-1 and the third-2 insulating layer 105-2 acting as a dielectric. The second storage electrode 142 may be made of the same material as the first storage electrode 141, but the embodiments of this specification are not limited thereto.

The second thin-film transistor 130 may be disposed to be spaced apart from the first thin-film transistor 120 and the storage electrode 140. The second thin-film transistor 130 may include a second source electrode 131, a second gate electrode 132, a second semiconductor layer 133, and a second drain electrode 134.

A second light-blocking layer 136 may be disposed in the same layer as the second storage electrode 142.

The second light-blocking layer 136, similar to the first light-blocking layer 126, may prevent light from reaching the second semiconductor layer 133, thereby extending the lifespan of the second thin-film transistor 130. For example, the second semiconductor layer 133 may be disposed for overlapping with the second light-blocking layer 136.

The fourth insulating layer 106 may be disposed on the second light-blocking layer 136. The fourth insulating layer 106 may be made of the same material as the first insulating layer 103, the second insulating layer 104, the third-1 insulating layer 105-1, or the third-2 insulating layer 105-2, but the embodiments of this specification are not limited thereto.

The second semiconductor layer 133 may be disposed on the fourth insulating layer 106. The second semiconductor layer 133 may include a source region, a drain region, and a channel region between the source and drain regions.

The second semiconductor layer 133 may include a semiconductor material such as a metal oxide semiconductor like Indium-Gallium-Zinc Oxide (IGZO), or a silicon-based semiconductor material such as amorphous silicon or polycrystalline silicon, but the embodiments of this specification are not limited thereto. For example, the second semiconductor layer 133 may be made of polycrystalline silicon in view of the higher mobility of the polycrystalline semiconductor, as described above.

The fifth insulating layer 108 may be disposed on the second semiconductor layer 133. The fifth insulating layer 108 may be made of the same material as the first insulating layer 103, the second insulating layer 104, the third-1 insulating layer 105-1 and the third-2 insulating layer 105-2, or the fourth insulating layer 106, but the embodiments of this specification are not limited thereto

The second gate electrode 132 may be disposed on the fifth insulating layer 108.

The second gate electrode 132 may be made of the same material as the first gate electrode 122. For example, the second gate electrode 132 may be formed as a single layer or multiple layers made from materials such as molybdenum (Mo), copper (Cu), titanium (Ti), aluminum (Al), chromium (Cr), gold (Au), nickel (Ni), neodymium (Nd), or alloys of these materials, but the embodiments of this specification are not limited thereto

The sixth insulating layer 109 may be disposed on the second gate electrode 132. The sixth insulating layer 109 may be made of the same material as the first insulating layer 103, second insulating layer 104, third-1 insulating layer 105-1 and third-2 insulating layer 105-2, the fourth insulating layer 106, or fifth insulating layer 108, but the embodiments of this specification are not limited thereto

The first source electrode 121, first drain electrode 124, second source electrode 131, and second drain electrode 134 may be disposed on the sixth insulating layer 109.

The second source electrode 131 and second drain electrode 134 may be made of the same material as the first source electrode 121 and first drain electrode 124 and may be disposed in the same layer, but the embodiments of this specification are not limited thereto For example, the second source electrode 131 and second drain electrode 134 may be formed as a single layer or multiple layers made from materials such as molybdenum (Mo), aluminum (Al), chromium (Cr), gold (Au), titanium (Ti), nickel (Ni), neodymium (Nd), and copper (Cu) or alloys of these materials, but the embodiments of this specification are not limited thereto. For example, the second source electrode 131 may be electrically connected to the second storage electrode 142. The second source electrode 131 may be electrically connected to the second storage electrode 142 by passing through the sixth insulating layer 109, fifth insulating layer 108, and fourth insulating layer 106.

The first thin-film transistor 120 may be a switching transistor, and the second thin-film transistor 130 may be a driving transistor, but the embodiments of this specification are not limited thereto

The first protective layer 111 may be disposed on the first source electrode 121 and the first drain electrode 124.

The first protective layer 111 may flatten the upper part of the first thin-film transistor 120 and protect the first thin-film transistor 120. The first protective layer 111 may be made of an organic material. For example, the first protective layer 111 may be made of an organic material such as acrylic resin, epoxy resin, phenolic resin, polyamide resin, or polyimide resin, but the embodiments of this specification are not limited thereto

The second protective layer 112 may be disposed on the first protective layer 111. The second protective layer 112 may be formed of the same material as the first protective layer 111, but the embodiments of this specification are not limited thereto

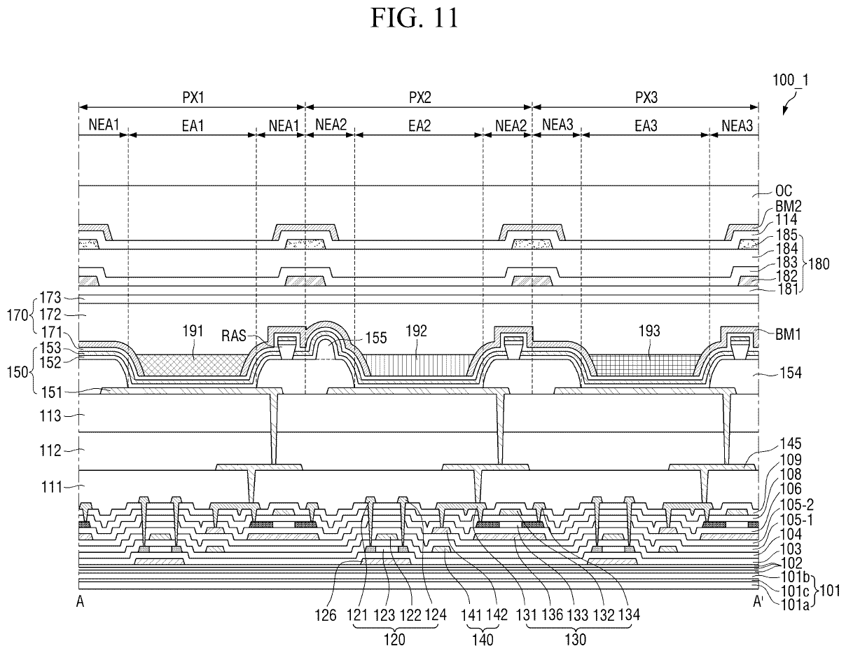

In some embodiments, a third protective layer 113 (FIG. 11) may be further disposed on the upper surface of the second protective layer 112, but the embodiments of this specification are not limited thereto

A connection electrode 145 may be disposed between the first protective layer 111 and the second protective layer 112.

The connection electrode 145 may electrically connect the first thin-film transistor 120 and the light-emitting element layer 150. The connection electrode 145 may be made of the same material as the first source electrode 121 and the first drain electrode 124, but the embodiments of this specification are not limited thereto

The connection electrode 145 may be a single layer or multilayer made from materials such as molybdenum (Mo), aluminum (Al), chromium (Cr), gold (Au), titanium (Ti), nickel (Ni), neodymium (Nd), and copper (Cu) or alloys of these materials, but the embodiments of this specification are not limited thereto

The light-emitting element layer 150 may be disposed on the second protective layer 112. The light-emitting element layer 150 may include an anode electrode 151, an light-emitting layer 152, and a cathode electrode 153.

The anode electrode 151 may be disposed on the second protective layer 112. The anode electrode 151 may be electrically connected to the first thin-film transistor 120 through a contact hole formed in the second protective layer 112. The anode electrode 151 may be a reflective electrode that reflects light, but the embodiments of this specification are not limited thereto. The anode electrode 151 may include a laminated structure (Ti/Al/Ti) of aluminum (Al) and titanium (Ti), a laminated structure (ITO/Al/ITO) of aluminum (Al) and ITO, or a high-reflectivity metal material such as APC alloy, and may be formed as a single layer or multiple layers, but the embodiments of this specification are not limited thereto.

The light-emitting layer 152 may be disposed on the anode electrode 151. The light-emitting layer 152 may include one or more light-emitting structures (or light-emitting devices or elements) stacked in either a hole-delivery layer and electron-delivery layer order, or the reverse order, on the anode electrode 151. For example, the hole delivery layer may include a hole transport layer, hole injecting layer, electron blocking layer, or P-type charge generating layer, but the embodiments of this specification are not limited thereto. For example, the electron delivery layer may include an electron transport layer, electron injecting layer, hole blocking layer, or N-type charge generating layer, but the embodiments of this specification are not limited thereto. The light-emitting layer 152 may be an organic light-emitting layer, an inorganic light-emitting layer, a quantum dot light-emitting layer, a micro light-emitting diode, or a micro-mini light-emitting diode, but the embodiments of this specification are not limited thereto. For example, the display panel 100 according an embodiment of this specification, the light-emitting layer 152 may include an organic light-emitting layer. The light-emitting layer 152 may include a red light-emitting layer, a green light-emitting layer, and a blue light-emitting layer. The light-emitting layer 152 may further include a white light-emitting layer, but the embodiments of this specification are not limited thereto. Hereinafter, the detailed structure of the light-emitting layer 152 according to an embodiment will be described.

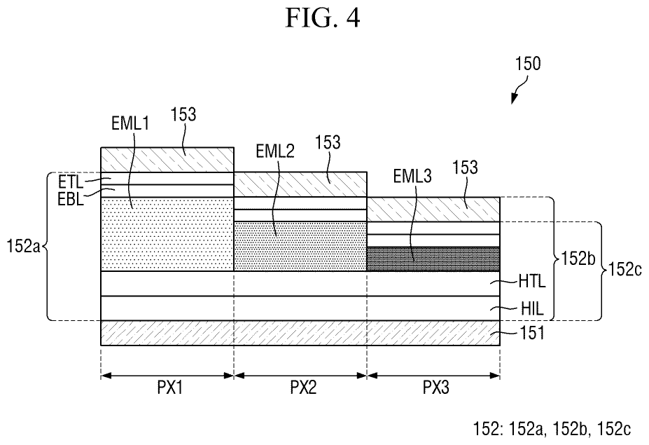

FIG. 4 is a detailed cross-sectional view of the lighting-emitting element layer of FIG. 3.

Referring to FIG. 4, the light-emitting element layer 150 may extend across a first sub-pixel PX1, a second sub-pixel PX2, and a third sub-pixel PX3.

The thickness of the light-emitting element layer 150 may differ in each sub-pixel (PX1, PX2, and PX3), but the embodiments of this specification are not limited thereto, and the thickness of the light-emitting element layer 150 in each sub-pixel (PX1, PX2, and PX3) may also be the same.

The light-emitting layer 152 may include a first light-emitting layer 152a disposed in the first sub-pixel PX1, a second light-emitting layer 152b disposed in the second sub-pixel PX2, and a third light-emitting layer 152c disposed in the third sub-pixel PX3. A first to third emissive layers EML1, EML2, and EML3 in the respective first to third light-emitting layers 152a, 152b, and 152c may be physically separated, but the lower and upper layers respectively disposed below and on the first to third emissive layers EML1, EML2, and EML3 may be integrally formed across the first to third sub-pixels PX1, PX2, and PX3. The first to third emissive layers EML1, EML2, and EML3 may differ in thickness. For example, the thickness of the first emissive layer EML1 may be the largest, followed by the second emissive layer EML2, and the thickness of the third emissive layer EML3 may be the smallest, but the embodiments of this specification are not limited thereto. The first emissive layer EML1 may emit red (R) light, the second emissive layer EML2 may emit green (G) light, and the third emissive layer EML3 may emit blue (B) light.

A hole injection layer HIL may be disposed on the anode electrode 151. The hole injection layer HIL may be positioned between the anode electrode 151 and the first to third emissive layers EML1, EML2, and EML3. The hole injection layer HIL may be integrally formed across the first to third sub-pixels PX1, PX2, and PX3. For example, the hole injection layer HIL may be made of a hole injection material selected from the group of MTDATA, CuPc, TCTA, NPB (NPD), HATCN, TDAPB, PEDOT/PSS, F4TCNQ, and N-(biphenyl-4-yl)-9,9-dimethyl-N-(4-(9-phenyl-9H-carbazole-3-yl)phenyl)-9H-fluorene-2-amine, but the embodiments of this specification are not limited thereto.

A hole transport layer HTL may be disposed on the hole injection layer HIL. The hole transport layer HTL may be positioned between the hole injection layer HIL and the first to third emissive layers EML1, EML2, and EML3. The hole transport layer HTL may be integrally formed across the first to third sub-pixels PX1, PX2, and PX3. The hole transport layer HTL may be made of one or more materials selected from a group including aryloamine-based compounds such as NPB (N,N′-naphthyl-N, N′-phenyl benzidine), TPD (N,N′-bis-(3-methylphenyl)-N, N′-bis-(phenyl)-benzidine), PPD, TTBND, FFD, p-dmDPS, TAPC, starburst aromatic amines such as TCTA, PTDATA, TDAPB, TDBA, 4-a, TCTA, spiro and ladder-type materials such as Spiro-TPD, Spiro-mTTB, Spiro-2, NPD (N, N-dinaphthyl-N, N′-diphenyl benzidine), S-TAD, and MTDATA (4,4′,4″-Tris(N-3-methylphenyl-N-phenyl-amino)-triphenylamine), but the embodiments of this specification are not limited thereto.

The first to third emissive layers EML1, EML2, and EML3 may be disposed on the hole transport layer HTL. The first sub-pixel PX1 may have the first emissive layer EML1, the second sub-pixel PX2 may have the second emissive layer EML2, and the third sub-pixel PX3 may have the third emissive layer EML3.

The first to third emissive layers EML1, EML2, and EML3 may differ in thickness. For example, the first emissive layer EML1 may have a thickness of 600 to 800 Å, the second emissive layer EML2 may have a thickness of 300 to 500 Å, and the third emissive layer EML3 may have a thickness of 100 to 300 Å, but the embodiments of this specification are not limited thereto.

The first emissive layer EML1, the second emissive layer EML2, and the third emissive layer EML3 may include materials that emit light in the visible light spectrum by combining holes and electrons, which are transported separately.

An electron blocking layer EBL may be disposed on each of the first to third emissive layers EML1, EML2, and EML3. The electron blocking layer EBL may be integrally disposed across the first to third sub-pixels PX1, PX2, and PX3.

An electron transport layer ETL may be disposed on the electron blocking layer EBL. The electron transport layer ETL may be integrally disposed across the first to third sub-pixels PX1, PX2, and PX3. The electron transport layer ETL may be composed of anthracene derivatives and lithium quinolate (Liq), or one or more materials selected from oxadiazole, triazole, phenanthroline, benzoxazole, benzthiazole, or benzimidazole (for example, 2-[4-(9,10-Di-2-naphthalenyl-2-anthracenyl)phenyl]-1-phenyl-1H-benzimidazole); however, the embodiments of this specification are not limited thereto.

The cathode electrode 153 may be disposed on the electron transport layer ETL.

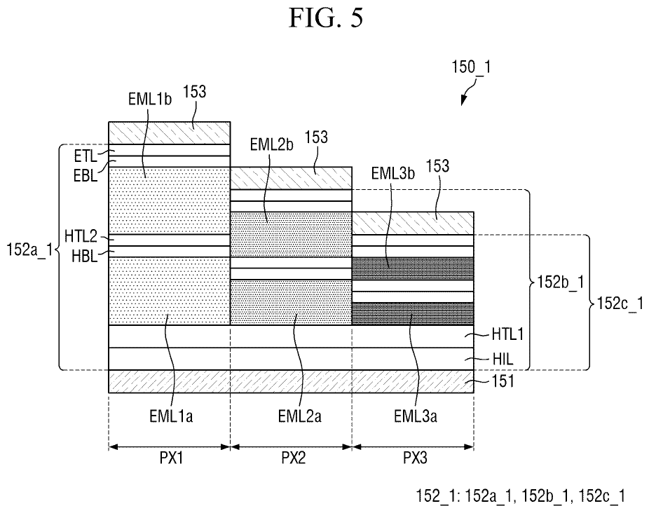

FIG. 5 is a detailed cross-sectional view of the light-emitting element layer of FIG. 3 according to an alternative embodiment;

Referring to FIGS. 4 and 5, the light-emitting layer 152_1 may include a first light-emitting layer 152a_1 disposed in the first sub-pixel PX1, a second light-emitting layer 152b_1 disposed in the second sub-pixel PX2, and a third light-emitting layer 152c_1 disposed in the third sub-pixel PX3.

The emissive layers in the respective first to third light-emitting layers 152a_1, 152b_1, and 152c_1 may be physically separated, but the lower and upper layers respectively disposed below and on the emissive layers may be integrally formed across the first to third sub-pixels PX1, PX2, and PX3. The emissive layers may differ in thickness. For example, the first emissive layer in the first sub-pixel may have the greatest thickness, followed by the second emissive layer in the second sub-pixel, with the third emissive layer in the third sub-pixel having the smallest thickness, but the embodiments of this specification are not limited thereto. Additionally, each of the first to third light-emitting layer 152a_1, 152b_1, and 152c_1 may include two or more emissive layers.

The hole injection layer HIL may be disposed on the anode electrode 151. The emissive layers may include a first-1 emissive layer EML1a, a second-1 emissive layer EML2a and a third-1 emissive layer EML3a. The hole injection layer HIL may be positioned between the anode electrode 151 and the first-1 emissive layer EML1a, the second-1 emissive layer EML2a, and the third-1 emissive layer EML3a. The hole injection layer HIL may be integrally formed across the first to third sub-pixels PX1, PX2, and PX3. For example, the hole injection layer HIL may be made of a hole injection material selected from the group of MTDATA, CuPc, TCTA, NPB (NPD), HATCN, TDAPB, PEDOT/PSS, F4TCNQ, and N-(biphenyl-4-yl)-9,9-dimethyl-N-(4-(9-phenyl-9H-carbazole-3-yl)phenyl)-9H-fluorene-2-amine, but the embodiments of this specification are not limited thereto.

The first hole transport layer HTL1 may be disposed on the hole injection layer HIL. The first hole transport layer HTL1 may be positioned between the hole injection layer HIL and the first-1 emissive layer EML1a, the second-1 emissive layer EML2a, and the third-1 emissive layer EML3a. The first hole transport layer HTL1 may be integrally formed across the first to third sub-pixels PX1, PX2, and PX3. The first hole transport layer HTL1 may be made of a material selected from a group including aryamine-based compounds such as NPB (N, N-naphthyl-N, N′-phenyl benzidine), TPD (N,N′-bis-(3-methylphenyl)-N, N′-bis-(phenyl)-benzidine), PPD, TTBND, FFD, p-dmDPS, TAPC, starburst aromatic amines such as TCTA, PTDATA, TDAPB, TDBA, 4-a, and TCTA, spiro and ladder type materials like Spiro-TPD, Spiro-mTTB, Spiro-2, as well as NPD (N, N-dinaphthyl-N, N′-diphenyl benzidine), s-TAD, and MTDATA (4,4′,4″-Tris(N-3-methylphenyl-N-phenyl-amino)-triphenylamine), but the embodiments of this specification are not limited thereto.

The first-1 emissive layer EML1a, the second-1 emissive layer EML2a, and the third-1 emissive layer EML3a may be disposed on the first hole transport layer HTL1. The first sub-pixel PX1 may have the first-1 emissive layer EML1a, the second sub-pixel PX2 may have the second-1 emissive layer EML2a, and the third sub-pixel PX3 may have the third-1 emissive layer EML3a. The first-1 emissive layer EML1a, the second-1 emissive layer EML2a, and the third-1 emissive layer EML3a may be identical to the first to third emissive layers EML1, EML2, and EML3 in FIG. 4, respectively.

The first-1 emissive layer EML1a, the second-1 emissive layer EML2a, and the third-1 emissive layer EML3a may differ in thickness. For example, the first-1 emissive layer EML1a may be formed with a thickness of 600 to 800 Å, the second-1 emissive layer EML2a may be formed with a thickness of 300 to 500 Å, and the third-1 emissive layer EML3a may be formed with a thickness of 100 to 300 Å, but the embodiments of this specification are not limited thereto.

A hole blocking layer HBL may be disposed on each of the first-1 emissive layer EML1a, the second-1 emissive layer EML2a, and the third-1 emissive layer EML3a. The hole blocking layer HBL may be integrally disposed across the first to third sub-pixels PX1, PX2, and PX3.

A second hole transport layer HTL2 may be disposed on the hole-blocking layer HBL. The second hole transport layer HTL2 may be positioned between the hole blocking layer HBL and the first-1 emissive layer EML1b, the second-1 emissive layer EML2b, and the third-1 emissive layer EML3b. The second hole transport layer HTL2 may be integrally formed across the first to third sub-pixels PX1, PX2, and PX3. The material of the second hole transport layer HTL2 may be the same as that of the first hole transport layer HTL1, but the embodiments of this specification are not limited thereto.

The emissive layers may include a first-2 emissive layer EML1b, a second-2 emissive layer EML2b and a third-2 emissive layer EML3b. The first-2 emissive layer EML1b, the second-2 emissive layer EML2b, and the third-2 emissive layer EML3b may be disposed on the second hole transport layer HTL2. The first sub-pixel PX1 may have the first-2 emissive layer EML1b, the second sub-pixel PX2 may have the second-2 emissive layer EML2b, and the third sub-pixel PX3 may have the third-2 emissive layer EML3b. The first-2 emissive layer EML1b, the second-2 emissive layer EML2b, and the third-2 emissive layer EML3b may be identical to the first-1 emissive layer EML1a, the second-1 emissive layer EML2a, and the third-1 emissive layer EML3a, respectively.

The first-2 emissive layer EML1b, the second-2 emissive layer EML2b, and the third-2 emissive layer EML3b may differ in thickness. For example, the first-2 emissive layer EML1b may be formed with a thickness of 600 to 800 Å, the second-2 emissive layer EML2b may be formed with a thickness of 300 to 500 Å, and the third-2 emissive layer EML3b may be formed with a thickness of 100 to 300 Å, but the embodiments of this specification are not limited thereto.

An electron blocking layer EBL may be disposed on each of the first-2 emissive layer EML1b, the second-2 emissive layer EML2b, and the third-2 emissive layer EML3b. The electron blocking layer EBL may be integrally disposed across the first to third sub-pixels PX1, PX2, and PX3.

An electron transport layer ETL may be disposed on the electron blocking layer EBL. The electron transport layer ETL may be integrally disposed across the first to third sub-pixels PX1, PX2, and PX3. The electron transport layer ETL may be composed of anthracene derivatives and lithium quinolate (Liq), or one or more materials selected from oxadiazole, triazole, phenanthroline, benzoxazole, benzthiazole, or benzimidazole (for example, 2-[4-(9,10-Di-2-naphthalenyl-2-anthracenyl)phenyl]-1-phenyl-1H-benzimidazole); however, the embodiments of this specification are not limited thereto.

The cathode electrode 153 may be disposed on the electron transport layer ETL.

Referring back to FIG. 3, the cathode electrode 153 may be disposed on the light-emitting layer 152. The cathode electrode 153 may be a transparent electrode that transmits light, but the embodiments of this specification are not limited thereto. For example, the cathode electrode 153 may include a transparent conductive material such as Indium Tin Oxide (ITO) or Indium Zinc Oxide (IZO), or a metal that allows visible light to pass through, but the embodiments of this specification are not limited thereto.

The bank 154 may be disposed to expose the anode electrode 151. The bank 154 may be disposed to cover the edge portion (or edge, or periphery) of the anode electrode 151. The bank 154 may define an emissive area and a non-emissive area surrounding the emissive area in a sub-pixel. The emissive area corresponds to an area exposed by the bank 154 and the non-emissive area corresponds to an area covered by the bank 154.

The bank 154 may include an organic insulating material. For example, the bank 154 may include an organic insulating material that is transparent. For example, the bank 154 may be a transparent bank. However, the embodiments of this specification are not limited thereto, and the bank 154 may also be a black bank including an organic insulating material in the black color series.

A barrier RAS may be further disposed on the bank 154. As shown in FIG. 3, the barrier RAS may be disposed along the boundaries (NEA1, NEA2, NEA3) between the first to third sub-pixels PX1, PX2, and PX3, but the embodiments of this specification are not limited thereto. The barrier RAS may be directly disposed on the upper surface of the bank 154, but the embodiments of this specification are not limited thereto. The barrier RAS may serve to separate the light-emitting layer 152 at the boundaries of adjacent sub-pixels of the first to third sub-pixels PX1, PX2, and PX3.

A spacer 155 may be further disposed on the bank 154. The spacer 155 may be made of the same material as the bank 154, but the embodiments of this specification are not limited thereto. For example, the spacer 155 may be a transparent bank, but is not limited thereto and may also be made of the same material as the bank 154. For example, the spacer 155 may be disposed at the boundaries of at least one of the first to third sub-pixels PX1, PX2, and PX3, but the embodiments of this specification are not limited thereto. The bank 154 and spacer 155 may be made from the same material and may be formed simultaneously through a half-tone mask, but the embodiments of this specification are not limited thereto.

The light-emitting layer 152 may be disposed on the anode electrode 151, the bank 154, and the spacer 155. The cathode electrode 153 may be disposed on the light-emitting layer 152.

The encapsulation layer 170 may be disposed on the cathode electrode 153. The encapsulation layer 170 may include one or more insulating layers. For example, the encapsulation layer 170 may include a first encapsulation layer 171, a second encapsulation layer 172 located on top of the first encapsulation layer 171, and a third encapsulation layer 173 located on top of the second encapsulation layer 172. The encapsulation layer 170 may include one or more inorganic insulating material layers and one or more organic material layers. For example, the first encapsulation layer 171 and the third encapsulation layer 173 may include inorganic insulating materials, while the second encapsulation layer 172 may include organic materials, but the embodiments of this specification are not limited thereto.

The display panel 100 according to an embodiment may further include a first black matrix (BM1). The first sub-pixel PX1 may include the first emissive area EA1 and the first non-emissive area NEA1 surrounding the first emissive area EA1, the second sub-pixel PX2 may include the second emissive area EA2 and the second non-emissive area NEA2 surrounding the second emissive area EA2, and the third sub-pixel PX3 may include the third emissive area EA3 and the third non-emissive area NEA3 surrounding the third emissive area EA3. In other words, the first to third non-emissive area NEA1, NEA2, and NEA3 may correspond to the boundaries between adjacent sub-pixels of the first to third sub-pixels PX1, PX2, and PX3.

The first black matrix BM1 may include a black-colored material. For example, the first black matrix BM1 may be composed of a material containing black pigments, or organic materials such as benzocyclobutene resin, polyimide resin, acrylic resin, or photosensitive polymers, but the embodiments of this specification are not limited thereto.

The first black matrix BM1 may be disposed between the first encapsulation layer 171 and the second encapsulation layer 172, and may be positioned at the boundary between adjacent sub-pixels of the first to third sub-pixels PX1, PX2, and PX3. For example, the first black matrix BM1 may be disposed in the first to third non-emissive areas NEA1, NEA2, and NEA3. The first black matrix BM1 may extend into some of the first to third emissive areas EA1, EA2, and EA3, and may come into direct contact with the sides of the first to third color filters 191, 192, and 193; however, the embodiments of this specification are not limited thereto.

The first to third color filters 191, 192, and 193 may be disposed on top of the first black matrix BM1 and the first encapsulation layer 171. The first to third color filters 191, 192, and 193 may be arranged in the first to third sub-pixels PX1, PX2, and PX3, respectively, to block specific colors from the light emitted from the first to third emissive areas EA1, EA2, and EA3 of the respective first to third sub-pixel PX1, PX2, and PX3. The first color filter 191 may be configured to block all colors except for red (R) light. In this case, the first color filter 191 may be a red color filter. The second color filter 192 may be configured to block all colors except for green (G) light. In this case, the second color filter 192 may be a green color filter. The third color filter 193 provided in the third sub-pixel PX3 may be configured to block all colors except for blue (B) light. In this case, the third color filter 193 may be a blue color filter. However, the embodiments of this specification are not limited to this configuration. Each of the first to third color filters 191, 192, and 193 may be disposed in the first to third emissive areas EA1, EA2, and EA3 and may not be disposed in the first to third non-emissive areas NEA1, NEA2, and NEA3; however, the embodiments of this specification are not limited thereto. Each of the first to third color filters 191, 192, and 193 may be spaced apart at the boundary between the first to third sub-pixels PX1, PX2, and PX3.

For example, the first to third color filters 191, 192, and 193 may be in contact with the side of the first black matrix BM1, but may not be in contact with the upper surface of the first black matrix BM1; however, the embodiments of this specification are not limited thereto.

The second encapsulation layer 172 may be disposed on the first to third color filters 191, 192, and 193 and the first black matrix BM1. The second encapsulation layer 172 may be in direct contact with the upper surfaces of the first to third color filters 191, 192, and 193, and the first black matrix BM1.

The touch layer 180 may be disposed on the encapsulation layer 170. The touch layer 180 may include a touch buffer layer 181, a first touch conductive layer, a first touch insulating layer 183, a second touch insulating layer 184, and a second touch conductive layer. In some embodiments, a touch organic layer (not shown) may be further disposed on the second touch conductive layer, but the embodiments of this specification are not limited thereto.

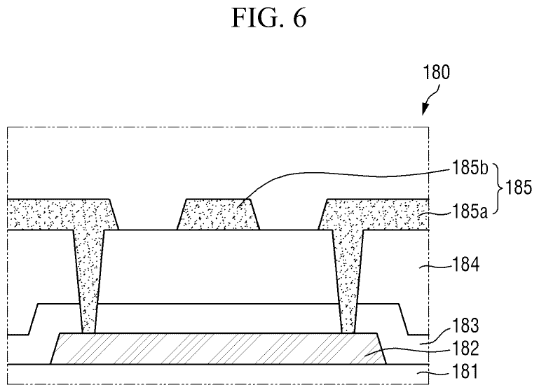

FIG. 6 is a cross-sectional view of the touch layer of FIG. 3;

Referring to FIGS. 3 and 6, the touch buffer layer 181 may be disposed on the encapsulation layer 170. For example, the touch buffer layer 181 may be disposed on the third encapsulation layer 173. The touch buffer layer 181 may be made of the same material as the buffer layer 102, but the embodiments of this specification are not limited thereto.

The first touch conductive layer may be disposed on the touch buffer layer 181. The first touch conductive layer may include a bridge electrode 182. The bridge electrode 182 and a sensor electrode 185, which will be described later, may be disposed at the boundaries between adjacent sub-pixels of the first to third PX1, PX2, and PX3. For example, the bridge electrode 182 and the sensor electrode 185 may be disposed in the first to third non-emissive areas NEA1, NEA2, and NEA3. The bridge electrode 182 and the sensor electrode 185 may overlap with the second black matrix BM2, which will be described later, in the thickness direction. The second black matrix BM2 may cover the bridge electrode 182 and the sensor electrode 185. As a result, the bridge electrode 182 and the sensor electrode 185 may be prevented from being visible from the outside.

The first touch insulating layer 183 and the second touch insulating layer 184 on top of the first touch insulating layer 183 may be disposed on the first touch conductive layer. The first touch insulating layer 183 and the second touch insulating layer 184 on top of the first touch insulating layer 183 may prevent a short circuit between the first touch conductive layer and the second touch conductive layer. The first touch insulating layer 184 may be formed of silicon oxide (Siox), silicon nitride (SiNx), or a multilayer thereof, but the embodiments of this specification are not limited thereto. The second touch insulating layer 184 may include an organic insulating material; however, the embodiments of this specification are not limited thereto and may also include the same material as the first touch insulating layer 184.

The second touch conductive layer may be disposed on the second touch insulating layer 184. The second touch conductive layer may include the sensor electrodes 185. The sensor electrodes 185 may include a first sensor electrode 185a extending in a first direction DR1 (see FIG. 1) and a second sensor electrode 185b extending in a second direction DR2 (see FIG. 1) different from the first direction DR1.

The bridge electrode 182 may be electrically connected to the first sensor electrode 185a through a contact hole formed in the first touch insulating layer 183 and the second touch insulating layer 184. For example, the first sensor electrode 185a and the bridge electrode 182 may extend in the first direction DR1 (see FIG. 1).

The sensor electrodes 185 and the bridge electrode 182 may include a metallic material. For example, they may be formed of titanium (Ti), nickel (Ni), aluminum (Al), or an alloy thereof and may be composed of three layers, such as titanium (Ti)/aluminum (Al)/titanium (Ti), but the embodiments of this specification are not limited thereto.

The upper insulating layer 114 may be disposed on the second touch conductive layer. The upper insulating layer 114 may be formed of an inorganic insulating material such as silicon nitride (SiNx) or silicon oxide (Siox), but the embodiments of this specification are not limited thereto.

The second black matrix BM2 may be disposed on the upper insulating layer 114. The second black matrix BM2 may include a black-colored material. For example, the second black matrix BM2 may include a light-blocking material or a light-absorbing material. For example, the second black matrix BM2 may be made of a material that includes black pigments or black dyes. The second black matrix BM2 may cover the bridge electrode 182 and the sensor electrode 185. As a result, the bridge electrode 182 and the sensor electrode 185 may be prevented from being visible from the outside. For example, the width of the second black matrix BM2 may be smaller than the width of the first black matrix BM1.

The planarization layer OC may be disposed on the second black matrix BM2. The planarization layer OC may serve to flatten the step difference formed by the sensor electrode 185. For example, the planarization layer OC may include an organic insulating material.

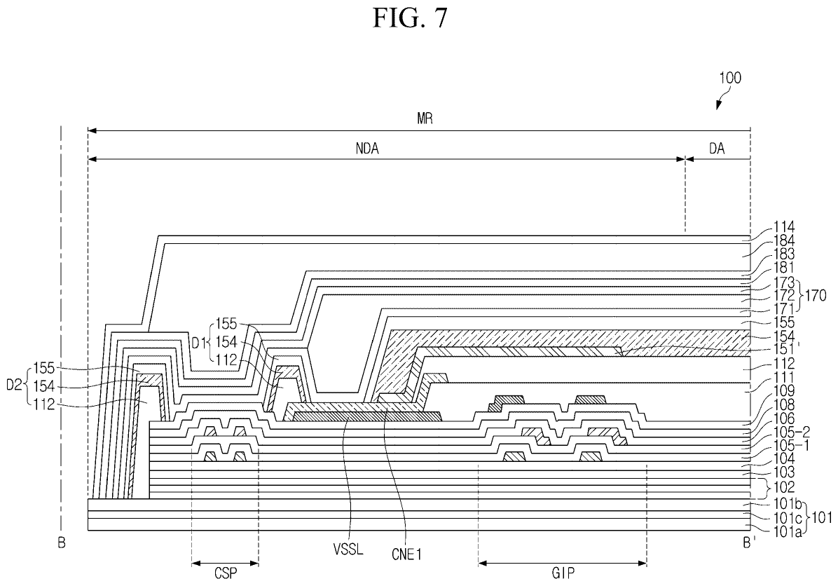

FIG. 7 is a cross-sectional view taken along line B-B′ of FIG. 1.

Referring to FIG. 7, at least one of the panel inorganic layers (102, 103, 104, 105-1, 105-2, 106, 108, and 109) may not extend to the edge of the substrate 101. That is, at least one of the panel inorganic layers (102, 103, 104, 105-1, 105-2, 106, 108, and 109) may expose the edge of the substrate 101, but the embodiments of this specification are not limited thereto.

In an embodiment, the display panel 100 may further include a crack detection pattern CSP, a low-potential voltage line VSSL, and a gate driving unit GIP. As described in FIG. 1, the low-potential voltage line VSSL may be located between the crack detection pattern CSP and the display area DA, and the gate driving unit GIP may be located between the low-potential voltage line VSSL and the display area DA.

For example, the gate driving unit GIP may include a conductive layer positioned in the same layer as the first gate electrode 122 (see FIG. 3), a conductive layer positioned in the same layer as the second light-blocking layer 136 (see FIG. 3), and a conductive layer positioned in the same layer as the first source electrode 121, but the embodiments of this specification are not limited thereto.

For example, the crack detection pattern CSP may be arranged between the first dam D1 and the second dam D2. The crack detection pattern CSP may be composed of a conductive layer positioned in the same layer as the first gate electrode 122 (see FIG. 3) and a conductive layer positioned in the same layer as the second light-blocking layer 136 (see FIG. 3), but the embodiments of this specification are not limited thereto. For example, the crack detection pattern CSP may include a conductive layer positioned in the same layer as the first source electrode 121, but the embodiments of this specification are not limited thereto.

The low-potential voltage line VSSL may be arranged between the crack detection pattern CSP and the gate driving unit GIP. The low-potential voltage line VSSL may be composed of a conductive layer positioned in the same layer as the first source electrode 121, but the embodiments of this specification are not limited thereto.

The first protective layer 111 may cover the gate driving unit GIP, partially cover one end of the low-potential voltage line VSSL, and expose the other end of the low-potential voltage line VSSL. In this specification, one end refers to the area located closer to the display area DA in the direction towards the display area DA from the non-display area NDA, and the other end refers to the area located closer to the non-display area NDA in the direction towards the non-display area NDA from the display area DA.

The first connection electrode CNE1 disposed on the first protective layer 111 may be arranged in the same layer as the connection electrode 145. The first connection electrode CNE1 may be directly connected to the other end of the low-potential voltage line VSSL exposed by the first protective layer 111. The first connection electrode CNE1 may cover the other end of the low-potential voltage line VSSL, but the embodiments of this specification are not limited thereto.

The second protective layer 112 may be arranged on the first connection electrode CNE1. The second protective layer 112 may directly contact and cover one end of the first connection electrode CNE1, while exposing the other end of the first connection electrode CNE1. The second protective layer 112 may constitute the first layer of the first dam D1 and the first layer of the second dam D2. The first dam D1 may overlap with, for example, the low-potential voltage line VSSL and cover the other end of the low-potential voltage line VSSL. The first dam D1 may directly contact the first connection electrode CNE1 and cover the other end of the first connection electrode CNE1. The second protective layer 112, which forms the first layer of the first dam D1, may directly contact the exposed side surfaces of at least one of the panel inorganic layers (102, 103, 104, 105, 106, 107, and 109), and may directly contact the upper surface of the substrate 101, but the embodiments of this specification are not limited thereto. The second protective layer 112 may overlap with the gate driving unit GIP. Although the dam is illustrated as consisting of two parts (i.e. the first dam D1 and the second dam D2) in this specification, the dam may be composed of three or more parts, or even just one part.

A low-potential connection electrode 151′ positioned in the same layer as the anode electrode 151 (see FIG. 3) may be placed on a portion of the first connection electrode CNE1 exposed by the second protective layer 112 and on top of the second protective layer 112. The low-potential connection electrode 151′ may be electrically connected to the portion of the first connection electrode CNE1 exposed by the second protective layer 112. The low-potential connection electrode 151′ may be electrically connected to the cathode electrode 153 (see FIG. 3) as described with reference to FIG. 3.

The bank 154 may be disposed on top of the low-potential connection electrode 151′ and the second protective layer 112. The bank 154 may overlap with the gate driving unit GIP and the low-potential connection electrode 151′, covering the other end of the low-potential connection electrode 151′. The bank 154 may fully cover the low-potential connection electrode 151′, but the embodiments of this specification are not limited thereto. The bank 154 may expose the center and the other end of the first connection electrode CNE1, but the embodiments of this specification are not limited thereto. The bank 154 may form the second layer of the first dam D1 and the second layer of the second dam D2. In each of the first dam D1 and the second dam D2, the bank 154 may overlap with the second protective layer 112 forming the first layer and may completely cover the second protective layer 112, but the embodiments of this specification are not limited thereto. In the second dam D2, the bank 154 may contact the side of the second protective layer 112 and the upper surface of the substrate 101, but the embodiments of this specification are not limited thereto.

The spacer 155 may be disposed on the bank 154. The spacer 155 may overlap with the gate driving unit GIP. The spacer 155 may form the third layer of the first and second dams D1 and D2. The spacer 155 forming the third layer of each of the first and second dams D1 and D2 may overlap with the bank 154 forming the second layer and may completely cover the bank 154, but the embodiments of this specification are not limited thereto. In the second dam D2, the spacer 155 may contact the side of the bank 154 and the upper surface of the substrate 101, but the embodiments of this specification are not limited thereto.

The encapsulation layer 170 may be disposed on the spacer 155. The first encapsulation layer 171 extends to the gate driving unit GIP, the low-potential voltage line VSSL, the first dam D1, and the second dam D2, and may cover the outer surface of the second dam D2. The second encapsulation layer 172 may terminate at the first dam D1. The second encapsulation layer 172 may overlap with the gate driving unit GIP and the low-potential voltage line VSSL. The third encapsulation layer 173 extends to the gate driving unit GIP, the low-potential voltage line VSSL, the first dam D1, and the second dam D2, and may directly contact the first encapsulation layer 171 on the first dam D1, the crack detection pattern CSP, and the second dam D2.

The touch buffer layer 181 and the first touch insulating layer 183 extend to the gate driving unit GIP, the low-potential voltage line VSSL, the first dam D1, and the second dam D2, and may cover the outer surface of the second dam D2. The second touch insulating layer 184 extends to the gate driving unit GIP, the low-potential voltage line VSSL, the first dam D1, and the crack detection pattern CSP, and may terminate on the second dam D2, but the embodiments of this specification are not limited thereto.

The upper insulating layer 114 extends to the gate driving unit GIP, the low-potential voltage line VSSL, the first dam D1, and the second dam D2, and may directly contact the outer surface of the second touch insulating layer 184, but the embodiments of this specification are not limited thereto.

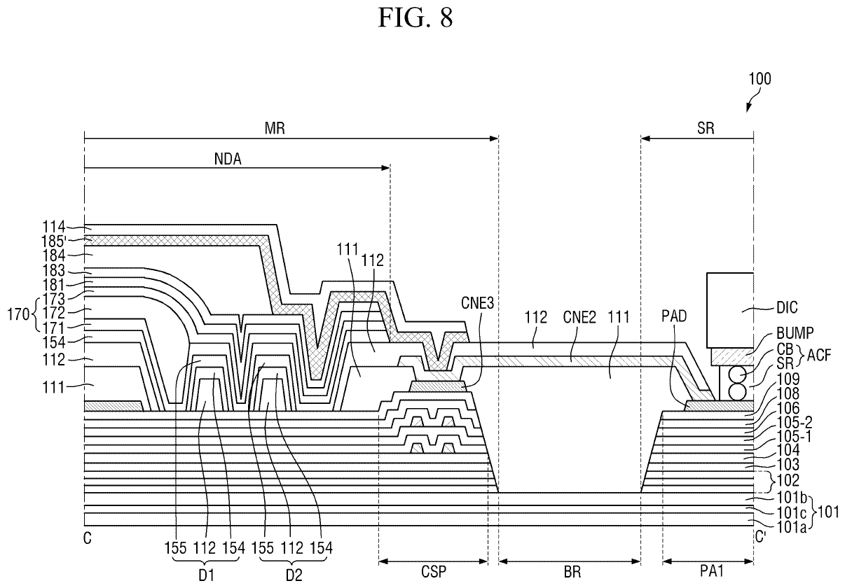

FIG. 8 is a cross-sectional view taken along line C-C′ of FIG. 1.

Referring to FIG. 3, FIG. 7, and FIG. 8, the bending region BR may be disposed between the sub-region SR and the crack detection pattern CSP. In the bending region BR, the panel inorganic layers (102, 103, 104, 105, 106, 107, and 109) may be removed, exposing the upper surface of the substrate 101.

In the first pad area PA1, a pad electrode PAD disposed in the same layer as the first source electrode 121 (see FIG. 3) is arranged, and a third connection electrode CNE3 disposed in the same layer as the first source electrode 121 (see FIG. 3) may be arranged on the crack detection pattern CSP.

The first protective layer 111 may be disposed on the pad electrode PAD and the third connection electrode CNE3. The first protective layer 111 is arranged in the bending region BR to directly contact the upper surface of the substrate 101 and the side surfaces of the panel inorganic layers (102, 103, 104, 105, 106, 107, and 109).

A second connection electrode CNE2 is arranged on the first protective layer 111, which may be positioned in the same layer as the connection electrode 145 (see FIG. 3). The second connection electrode CNE2 may electrically connect the pad electrode PAD and the third connection electrode CNE3. The second connection electrode CNE2 may be arranged across the bending region BR and the first pad area PA1 and above the crack detection pattern CSP.

The data driving unit DIC may be arranged on the pad electrode PAD. The data driving unit DIC includes bumps BUMP, and an anisotropic conductive film ACF is disposed between the pad electrode PAD and the bumps BUMP, electrically connecting the pad electrode PAD and the bumps BUMP. The anisotropic conductive film ACF may include a resin SR and a plurality of conductive balls CB dispersed in the resin SR. Through the conductive balls CB, the pad electrode PAD, and the bumps BUMP may be electrically connected.

The second protective layer 112 may be disposed on the second connection electrode CNE2. The second protective layer 112 may expose the pad electrode PAD.

The first and second encapsulation layers 171 and 173 of the encapsulation layer 170 may extend to the bending region BR. For example, the first and second encapsulation layers 171 and 173 may extend to the crack detection pattern CSP and may also overlap with the crack detection pattern CSP, but the embodiments of this specification are not limited thereto. The first and second encapsulation layers 171 and 173 may not be disposed in the bending region BR.

The touch buffer layer 181 and the first touch insulating layer 183 may extend to the bending region BR. For example, the touch buffer layer 181 and the first touch insulating layer 183 may extend to the crack detection pattern CSP and may also overlap with the crack detection pattern CSP, but the embodiments of this specification are not limited thereto. The touch buffer layer 181 and the first touch insulating layer 183 may not be disposed in the bending region BR.

The second touch insulating layer 184 may overlap with the first dam D1 and the second dam D2. The second touch insulating layer 184 may not be disposed on the outer side of the second dam D2, but the embodiments of this specification are not limited thereto.

A touch connection wiring 185′ may be electrically connected to the second connection electrode CNE2. The touch connection wiring 185′ may serve to provide the signal applied from the pad electrode PAD and the second connection electrode CNE2 to the first sensor electrode 185a or the second sensor electrode 185b, as described with reference to FIG. 3. The touch connection wiring 185′ may be located in the same layer as the second touch conductive layer (first sensor electrode 185a in FIG. 3) or may also be located in the same layer as the first touch conductive layer (bridge electrode 182 in FIG. 3) or consist of two layers of the first and second touch conductive layers, but the embodiments of this specification are not limited thereto.

The upper insulating layer 114 may be disposed on the touch connection wiring 185′, and the upper insulating layer 114 may not be disposed in the bending area BR.

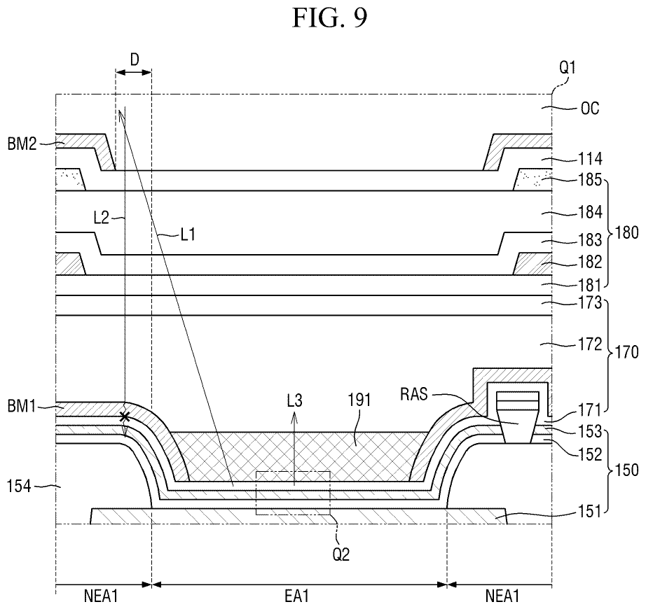

FIG. 9 is an enlarged cross-sectional view of Q1 area of FIG. 3.

As described before, the second black matrix BM2 may have a width smaller than the width of the first black matrix BM1. Thus, the edge of the second black matrix BM2 may be disposed away from the emissive area relative to the edge of the first black matrix BM1. Referring to FIG. 9, in the first sub-pixel PX1, the distance D between the edge of the second black matrix BM2 and the boundary between the first emissive area EA1 and the first non-emissive area NEA1 may be longer than the distance between the edge of the first black matrix BM1 and the boundary between the first emissive area EA1 and the first non-emissive area NEA1. That is, the edge of the first black matrix BM1 may be arranged closer to first emissive area EA1 than the edge of the second black matrix BM2. The edge of the first black matrix BM1 may be aligned with the boundary between the first emissive area EA1 and the first non-emissive area NEA1, but the embodiments of this specification are not limited thereto. For another example, the edge of the first black matrix BM1 may extend into the first emissive area EA1, as shown in FIG. 9. In the display panel 100 according to an embodiment, since the first black matrix BM1 includes a black-colored material and the distance between the edge of the second black matrix BM2 and the boundary between the first emissive area EA1 and the first non-emissive area NEAL is longer than the distance between the edge of the first black matrix BM1 and the boundary between the first emissive area EA1 and the first non-emissive area NEA1, the light emitted from the first emissive area EA1 as the first light L1 may have a wider viewing angle and be emitted upwards due to the larger space between the edge of the second black matrix BM2 and the boundary between the first emissive area EA1 and the first non-emissive area NEA1. As a result, the reduction in brightness due to the viewing angle can be improved. However, when the distance between the edge of the second black matrix BM2 and the boundary between the first emissive area EA1 and the first non-emissive area NEA1 is longer than the distance between the edge of the first black matrix BM1 and the boundary between the first emissive area EA1 and the first non-emissive area NEA1, and when the first black matrix BM1 is made of a transparent material, the second light L2 incident from the outside may be reflected by the first black matrix BM1, which may cause a halo stain to be visible. In a display panel 100 according to an embodiment, the second light L2 may be absorbed or blocked by the first black matrix BM1, which includes a black-colored material, thereby improving the occurrence of the halo stain. In the second and third sub-pixels PX2, PX3, the second black matrix BM2 may be configured in the same manner as in the first sub-pixel PX1, a detailed description thereof will be omitted.

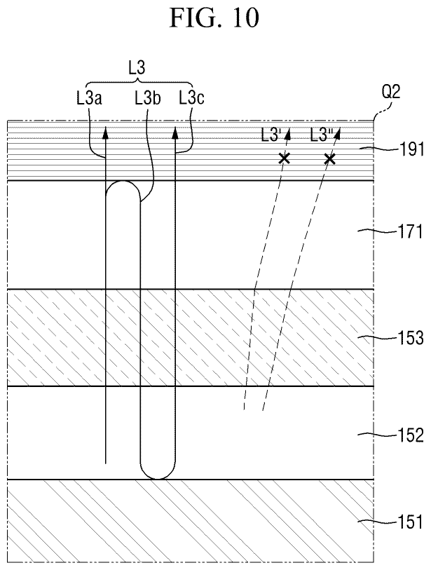

FIG. 10 is an enlarged cross-sectional view of Q2 area of FIG. 9.

Referring to FIG. 9 and FIG. 10, the third light L3 may be emitted from the light-emitting layer 152 in the first emissive area EA1. The third light L3 may include the third-1 light L3a, which passes through the first encapsulation layer 171 from the light-emitting layer 152 and is incident on the first color filter 191, the third-2 light L3b, which is reflected from the first color filter 191 among the third-1 light L3a, and the third-3 light L3c, which is re-reflected by the anode electrode 151 and incident on the first color filter 191 among the third-2 light L3b. In a display panel 100 according to an embodiment, the first color filter 191 (the second and third color filters 192 and 193 in the second and third sub-pixels PX2 and PX3 in FIG. 3) may be disposed between the first encapsulation layer 171 and the second encapsulation layer 172. That is, the first color filter 191 may be positioned closer to the light-emitting layer 152. As mentioned above, the first color filter 191 functions to block specific colors from the third light L3 emitted from the first emissive area EA1. As a result, light of different wavelengths (L3′ (e.g., green light), L3″ (e.g., blue light)) may be filtered between the first encapsulation layer 171 and the second encapsulation layer 172, as shown in FIG. 10. As shown in FIGS. 4 and 5, the light-emitting layer 152 in the first emissive area EA1 emits red (R) light, but some green (G) light or blue (B) light may be mixed in. However, in an embodiment, the first color filter 191 filters out light of different wavelengths (L3′ (e.g., green light), L3″ (e.g., blue light)) at a lower position, thereby preventing some green (G) light or blue (B) light from being transmitted to the adjacent sub-pixel areas (PX2 and PX3 in FIG. 3). As a result, the color purity of the display device can be improved, and color mixing can be prevented.

Furthermore, because the first color filter 191 is close to the anode electrode 151, there is a recycling effect, such as the third-2 light L3b reflected from the first color filter 191 and the third-3 light L3c, which is re-reflected by the anode electrode 151 and then incident on the first color filter 191 among the third-2 light L3b, thereby further enhancing the color purity of the display device.

Hereinafter, descriptions are provided of the display devices according to other embodiments. In the following embodiments, detailed explanations of the reference numerals or configurations already described with reference to FIGS. 1 to 10 will be omitted to avoid redundancy.

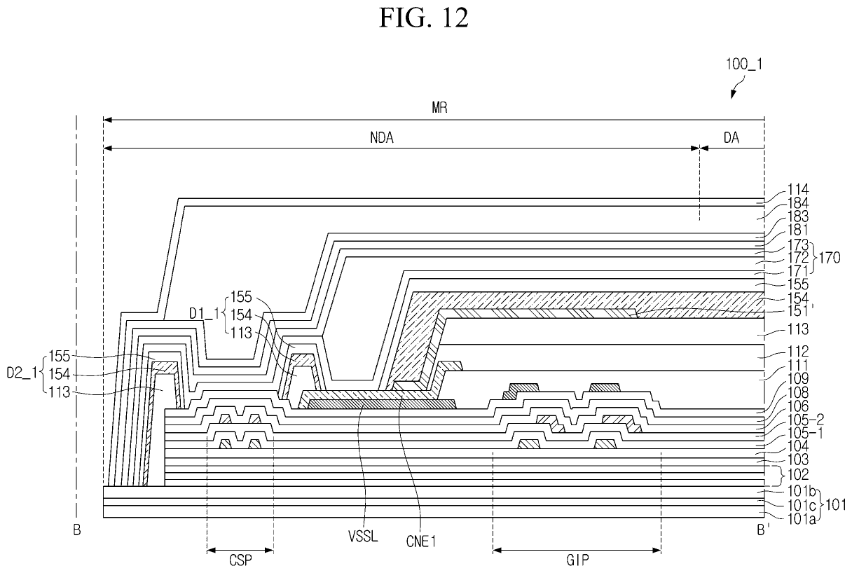

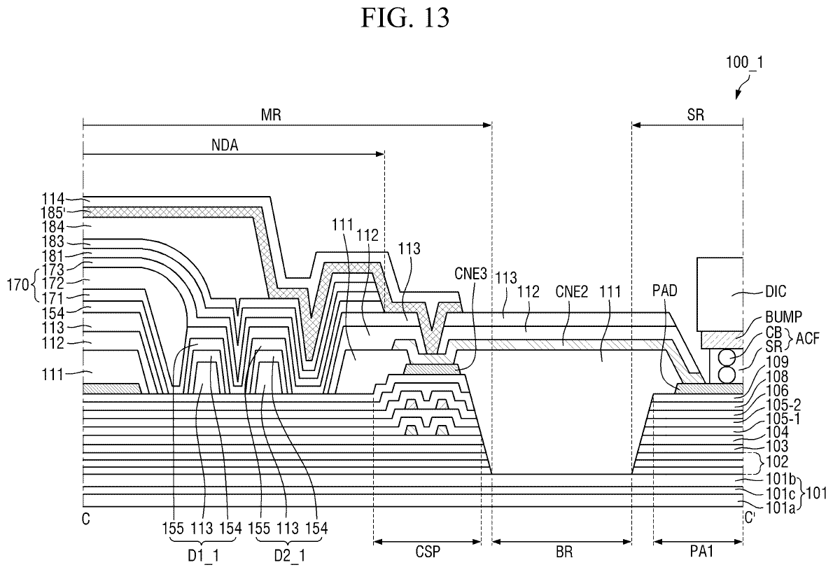

FIG. 11 is a cross-sectional view taken along line A-A′ of FIG. 1 of a display device according to another embodiment. FIG. 12 is a cross-sectional view taken along line B-B′ of FIG. 10f a display device according to another embodiment. FIG. 13 is a cross-sectional view taken along line C-C′ of FIG. 10f a display device according to another embodiment;

The display panel 100_1 of the display device according to the embodiment of FIGS. 11 to 13 differs from the display panel 100 according to the embodiment of FIGS. 3, 7, and 8 in that a third protective layer 113 is further included on the second protective layer 112.

In more detail, the display panel 100_1 according to this specification may further include a third protective layer 113 between the second protective layer 112 and the anode electrode 151. The material of the third protective layer 113 may include at least one of the materials exemplified for the second protective layer 112, but the embodiments of this specification are not limited thereto.

As shown in FIGS. 12 and 13, the first dam D1_1 and the second dam D2_1 each include the third protective layer 113 as a first layer and may not include the second protective layer 112; however, the embodiments of this specification are not limited thereto.

Other explanations are omitted as they have been detailed above with reference to FIGS. 3, 7, and 8.

The display device according to various embodiments of this specification may be described as follows.

A display device according to an embodiment of this specification includes a substrate, a light-emitting element layer on the substrate, a first encapsulation layer on the light-emitting element layer, a color filter on the first encapsulation layer, and a second encapsulation layer on the color filter.

In the display device according to the embodiments of this specification, the substrate may include a plurality of sub-pixels and the color filter is disposed in each of the plurality sub-pixels.

In the display device according to the embodiments of this specification, the light-emitting element layer may include an anode electrode disposed for each of the plurality of sub-pixels on the substrate, a light-emitting layer disposed on the anode electrode, and a cathode electrode on the light-emitting layer, wherein the first encapsulation layer may be disposed on the cathode electrode.

In the display device according to the embodiments of this specification, the display device may further include a bank disposed on the anode electrode, positioned at a boundary between adjacent sub-pixels of the plurality of sub-pixels, and overlapping a peripheral portion of an upper surface of the anode electrode.

In the display device according to the embodiments of this specification, the first encapsulation layer may comprise an inorganic insulating material, and the second encapsulation layer may comprise an organic insulating material

In the display device according to the embodiments of this specification, the color filter may be in direct contact with the first encapsulation layer and the second encapsulation layer.

The display device according to the embodiments of this specification may further include a first black matrix disposed at the boundary between adjacent sub-pixels, between the color filter and the first encapsulation layer.

In the display device according to the embodiments of this specification, the plurality of sub-pixels may include a first sub-pixel, a second sub-pixel, and a third sub-pixel, and the light-emitting layer may include a first light-emitting layer in the first sub-pixel, a second light-emitting layer in the second sub-pixel, and a third light-emitting layer in the third sub-pixel.

In the display device according to the embodiments of this specification, the first light-emitting layer, the second light-emitting layer, and the third light-emitting layer may each include two or more emissive layers stacked in each sub-pixel.

The display device according to the embodiments of this specification may further include a third encapsulation layer on the second encapsulation layer, and a second black matrix positioned at the boundary between the adjacent sub-pixels on the third encapsulation layer, wherein the second black matrix may have a width smaller than the width of the first black matrix.

In the display device according to the embodiments of this specification, the edge of the second black matrix may be closer to the boundary between the adjacent sub-pixels than the edge of the first black matrix.

The display device according to the embodiments of this specification may further include a touch layer on the third encapsulation layer, wherein the touch layer may include a bridge electrode and a sensor electrode on the bridge electrode, and the second black matrix may overlap with the bridge electrode and the sensor electrode.

In the display device according to the embodiments of this specification, the color filter may include a first color filter in the first sub-pixel, a second color filter in the second sub-pixel, and a third color filter in the third sub-pixel.

In the display device according to the embodiments of this specification, the first color filter, the second color filter, and the third color filter may be spaced apart from each other.

The display device according to the embodiments of this specification may further include a first transistor between the substrate and the anode electrode, and a second transistor between the first transistor and the anode electrode.

The display device according to the embodiments of this specification may further include a first protective layer between the second transistor and the anode electrode, a first connection electrode disposed on the first protective layer, and a second protective layer on the first connection electrode, wherein the first connection electrode electrically may connect the second transistor and the anode electrode.

In the display device according to the embodiments of this specification, the first transistor may include a semiconductor layer made of a metal oxide semiconductor, and the second transistor may include a semiconductor layer made of polycrystalline silicon.

In the display device according to the embodiments of this specification, the substrate may include a display area and a non-display area surrounding the display area, and the non-display area may include a low-potential voltage line and a gate driving unit between the low-potential voltage line and the display area.

In the display device according to the embodiments of this specification, the non-display area may further include a crack detection pattern outside the low-potential voltage line and a dam overlapping the low-potential voltage line.

In the display device according to the embodiments of this specification, each of the first black matrix and the second black matrix may comprise a black-colored material.

In the display device according to the embodiments of this specification, the bank may define an emissive area and a non-emissive area surrounding the emissive area in each sub-pixel, and the color filter may be arranged in the emissive area.

In the display device according to the embodiments of this specification, the edge of the first black matrix may be located in the emissive area and the edge of the second black matrix may be located in the non-emissive area.

In the display device according to the embodiments of this specification, the anode electrode may be a reflective electrode and the cathode electrode may be a transparent electrode.

A display device according to the embodiments of this specification includes a substrate including a plurality of sub-pixels, a light-emitting element layer on the substrate, an encapsulation layer including a first encapsulation layer on the light-emitting element layer, a second encapsulation layer on the first encapsulation layer, and a third encapsulation layer on the second encapsulation layer, a first black matrix disposed at the boundary between adjacent sub-pixels, between the first and second encapsulation layers, a color filter disposed between the first black matrix and the second encapsulation layer, a touch layer including a first touch conductive layer disposed on the third encapsulation layer and including a bridge electrode, and a second touch conductive layer disposed on the first touch conductive layer and including a sensor electrode, a second black matrix disposed at the boundary between adjacent sub-pixels on the touch layer, covering the bridge electrode and the sensor electrode, wherein the second black matrix has a width smaller than the width of the first black matrix.

In the display device according to the embodiments of this specification, the edge of the second black matrix may be closer to the boundary between the adjacent sub-pixels than the edge of the first black matrix.

In the display device according to the embodiments of this specification, the touch layer may further include a touch buffer layer between the third encapsulation layer and the first touch conductive layer, a first touch insulating layer between the first touch conductive layer and the second touch conductive layer, and a second touch insulating layer between the first touch insulating layer and the second touch conductive layer.

In the display device according to the embodiments of this specification, the first touch insulating layer may include an inorganic insulating material, and the second touch insulating layer may include an organic insulating material.

In the display device according to the embodiments of this specification, an upper insulating layer may be disposed on the second touch conductive layer and the second black matrix may be disposed on the upper insulating layer.

In the display device according to the embodiments of this specification, the light-emitting element layer may includes an anode electrode disposed for each of the plurality of sub-pixels on the substrate, a light-emitting layer disposed on the anode electrode, a cathode electrode on the light-emitting layer, wherein the first encapsulation layer may be disposed on the cathode electrode.

In the display device according to the embodiments of this specification, the display device may further include a bank disposed on the anode electrode, positioned at a boundary between adjacent sub-pixels of the plurality of sub-pixels, and overlapping a peripheral portion of an upper surface of the anode electrode.

The display device according to the embodiments is advantageous in terms of improving the color purity of light generated from the light-emitting element layer by placing the color filters between the first and second encapsulation layers. The display device according to the embodiments is

advantageous in terms of securing a viewing angle by positioning the edge of the second black matrix, which covers the sensor electrode, close to the boundary between adjacent sub-pixels and away from the boundary between the emissive and non-emissive areas, as compared to the edge of the first black matrix, which separates the color filters.

The display device according to the embodiments is advantageous in terms of improving luminance reduction and driving efficiency by positioning the edge of the second black matrix, which covers the sensor electrode, close to the boundary between adjacent sub-pixels and away from the boundary between the emissive and non-emissive areas, as compared to the edge of the first black matrix separating the color filters.

The display device according to the embodiments is advantageous in terms of reducing thickness by placing the color filters between the first and second encapsulation layers and designing the thickness of the second encapsulation layer to be the same as the previous design.

The display device according to the embodiments is advantageous in terms of achieving low power consumption without compromising high efficiency and high luminance, through improvements in luminance reduction and driving efficiency.

The advantages achievable through this specification are not limited to those mentioned above, and other advantages not explicitly described herein may be clearly understood by those skilled in the art from the disclosure.

Although embodiments of this invention have been described above with reference to the accompanying drawings, it will be understood that the technical configuration of the invention described above can be implemented in other specific forms by those skilled in the art without changing the technical concept or essential features of the present invention. Therefore, it should be understood that the embodiments described above are exemplary and not limited in all respects. Furthermore, the scope of the present invention is defined by the claims set forth below, rather than the detailed description above. In addition, it should be understood that all modifications or variations derived from the meaning and scope of the claims and their equivalent concept are included within the scope of the invention.

What is claimed is:

1. A display device, comprising:
a substrate;
a light-emitting element layer on the substrate;
a first encapsulation layer on the light-emitting element layer;
a color filter on the first encapsulation layer; and
a second encapsulation layer on the color filter.

2. The display device of claim 1, wherein the substrate includes a plurality of sub-pixels, and the color filter is disposed in each of the plurality of sub-pixels.

3. The display device of claim 2, wherein the light-emitting element layer includes:
an anode electrode disposed for each of the plurality of sub-pixels on the substrate;
a light-emitting layer disposed on the anode electrode; and
a cathode electrode on the light-emitting layer,
wherein the first encapsulation layer is disposed on the cathode electrode.

4. The display device of claim 3, further including a bank disposed on the anode electrode, positioned at a boundary between adjacent sub-pixels among the plurality of sub-pixels, and overlapping a peripheral portion of an upper surface of the anode electrode.

5. The display device of claim 1, wherein the first encapsulation layer comprises an inorganic insulating material, and the second encapsulation layer comprises an organic insulating material.

6. The display device of claim 1, wherein the color filter is in direct contact with the first encapsulation layer and the second encapsulation layer.

7. The display device of claim 4, further comprising a first black matrix disposed at the boundary between the adjacent sub-pixels, and between the color filter and the first encapsulation layer.

8. The display device of claim 7, wherein the plurality of sub-pixels comprise a first sub-pixel, a second sub-pixel, and a third sub-pixel, and the light-emitting layer comprises a first light-emitting layer in the first sub-pixel, a second light-emitting layer in the second sub-pixel, and a third light-emitting layer in the third sub-pixel.

9. The display device of claim 8, wherein each of the first light-emitting layer, the second light-emitting layer, and the third light-emitting layer includes two or more emissive layers stacked in a corresponding one of the first, second, and third sub-pixels.

10. The display device of claim 8, further comprising:
a third encapsulation layer on the second encapsulation layer; and
a second black matrix positioned at the boundary between the adjacent sub-pixels on the third encapsulation layer,
wherein the second black matrix has a smaller width than the first black matrix.

11. The display device of claim 10, wherein an edge of the second black matrix is closer to the boundary between the adjacent sub-pixels than an edge of the first black matrix.

12. The display device of claim 10, further comprising a touch layer on the third encapsulation layer,
wherein the touch layer comprises a bridge electrode and a sensor electrode on the bridge electrode, and the second black matrix overlaps with the bridge electrode and the sensor electrode.

13. The display device of claim 8, wherein the color filter comprises a first color filter in the first sub-pixel, a second color filter in the second sub-pixel, and a third color filter in the third sub-pixel.

14. The display device of claim 13, wherein the first color filter, the second color filter, and the third color filter are spaced apart from each other.

15. The display device of claim 1, further comprising:
a first transistor between the substrate and an anode electrode of the light-emitting element layer; and
a second transistor between the first transistor and the anode electrode.

16. The display device of claim 15, further comprising:
a first protective layer between the second transistor and the anode electrode;
a first connection electrode disposed on the first protective layer; and
a second protective layer on the first connection electrode,
wherein the first connection electrode electrically connects the second transistor and the anode electrode.

17. The display device of claim 15, wherein the first transistor comprises a semiconductor layer made of a metal oxide semiconductor, and the second transistor comprises a semiconductor layer made of polycrystalline silicon.

18. The display device of claim 1, wherein the substrate includes a display area and a non-display area surrounding the display area, and the non-display area comprises a low-potential voltage line and a gate driving unit between the low-potential voltage line and the display area.

19. The display device of claim 18, wherein the non-display area further comprises a crack detection pattern outside the low-potential voltage line and a dam overlapping the low-potential voltage line.

20. The display device of claim 11, wherein each of the first black matrix and the second black matrix comprises a black-colored material.

21. The display device of claim 11, wherein the bank defines an emissive area and a non-emissive area surrounding the emissive area in each sub-pixel, and the color filter is arranged in the emissive area.

22. The display device of claim 21, wherein an edge of the first black matrix is located in the emissive area, and an edge of the second black matrix is located in the non-emissive area.

23. The display device of claim 3, wherein the anode electrode is a reflective electrode, and the cathode electrode is a transparent electrode.

24. A display device, comprising:
a substrate comprising a plurality of sub-pixels;
a light-emitting element layer on the substrate;
an encapsulation layer comprising a first encapsulation layer on the light-emitting element layer, a second encapsulation layer on the first encapsulation layer, and a third encapsulation layer on the second encapsulation layer;
a first black matrix disposed at a boundary between adjacent sub-pixels, among the plurality of sub-pixels, and between the first and second encapsulation layers;
a color filter disposed between the first black matrix and the second encapsulation layer;
a touch layer comprising a first touch conductive layer disposed on the third encapsulation layer and including a bridge electrode, and a second touch conductive layer disposed on the first touch conductive layer and including a sensor electrode;
a second black matrix disposed at the boundary between the adjacent sub-pixels on the touch layer, covering the bridge electrode and the sensor electrode,
wherein the second black matrix has a smaller width than the first black matrix.

25. The display device of claim 24, wherein an edge of the second black matrix is closer to the boundary between the adjacent sub-pixels than an edge of the first black matrix.

26. The display device of claim 24, wherein the touch layer further comprises:
a touch buffer layer between the third encapsulation layer and the first touch conductive layer;
a first touch insulating layer between the first touch conductive layer and the second touch conductive layer; and
a second touch insulating layer between the first touch insulating layer and the second touch conductive layer.

27. The display device of claim 26, wherein the first touch insulating layer comprises an inorganic insulating material, and the second touch insulating layer comprises an organic insulating material.

28. The display device of claim 27, wherein an upper insulating layer is disposed on the second touch conductive layer, and the second black matrix is disposed on the upper insulating layer.

29. The display device of claim 24, wherein the light-emitting element layer includes:
an anode electrode disposed for each of the plurality of sub-pixels on the substrate;
a light-emitting layer disposed on the anode electrode;
a cathode electrode on the light-emitting layer,
wherein the first encapsulation layer is disposed on the cathode electrode.

30. The display device of claim 29, further comprising a bank disposed on the anode electrode, positioned at a boundary between adjacent sub-pixels among the plurality of sub-pixels, and overlapping a peripheral portion of an upper surface of the anode electrode.
